(19) United States
(12) Patent Application Publication
(10) Pub. No.: US 2019/0330736 A1
(43) Pub. Date: Oct. 31, 2019

(54) Low Temperature Atomic Layer Deposition Of Silicon Nitride

(71) Applicant: Applied Materials, Inc., Santa Clara, CA (US)

(72) Inventors: Huiyuan Wang, Santa Clara, CA (US); Pramit Manna, Sunnyvale, CA (US); Bo Qi, San Jose, CA (US); Abhijit Basu Mallick, Palo Alto, CA (US)

(21) Appl. No.: 16/397,155

(22) Filed: Apr. 29, 2019

Related U.S. Application Data
(60) Provisional application No. 62/664,233, filed on Apr. 29, 2018.

(51) Int. Cl. C23C 16/34; C23C 16/455; H01L 45/00

(52) U.S. Cl. CPC C23C 16/345; C23C 16/45538; H01L 45/141; H01L 45/06; H01L 45/1616; C23C 16/45553

(57) ABSTRACT

Methods of depositing a silicon nitride film at low temperatures are discussed. The silicon nitride films of some embodiments are highly conformal, have low etch rates, low atomic oxygen concentrations and/or good hermeticity. The films may be used to protect chalcogen materials in PCRAM devices. Some embodiments utilize an ALD process comprising a nitrogen precursor, a silicon precursor and a plasma treatment in each cycle. Some embodiments perform the plasma treatment at a lower pressure than the precursor exposures.

### CROSS-REFERENCE TO RELATED APPLICATIONS

This application claims priority to U.S. Provisional Application No. 62/664,233, filed Apr. 29, 2018, the entire disclosure of which is hereby incorporated by reference herein.

### FIELD

Embodiments of the disclosure generally relate to the fabrication of semiconductors, including processes for depositing and treating silicon nitride films. More particularly, certain embodiments of the disclosure are directed to methods for depositing silicon nitride encapsulation layers for PCRAM devices.

### BACKGROUND

Phase change random-access memory (PCRAM) is a type of emerging non-volatile memory with an increasing number of applications and fast market growth. PCRAM relies on a phase change layer consisting of a chalcogenide material. The chalcogenide materials are sensitive to air and moisture. Silicon nitride (SiN) thin films can be used as encapsulation layers over the chalcogenide materials.

Many conventional methods used to deposit SiN films have drawbacks. Some methods, such as chemical vapor deposition (CVD), rely on higher temperatures that can damage devices. Some methods, such as plasma enhanced chemical vapor deposition (PECVD), form non-conformal films. Still other methods may use precursors that can etch chalcogenide materials, such as chlorine-containing precursors. And still other methods may result in films that contain high levels of impurities which can adversely affect film quality.

Therefore, there is a need in the art for methods that use chalcogenide-friendly precursors to form conformal and hermetic SiN films at lower temperatures.

### SUMMARY

One or more embodiments of the disclosure are directed to a deposition method. The method comprises providing a substrate with at least one three dimensional structure formed thereon. The substrate is sequentially exposed to a silicon halide precursor and a nitrogen precursor to form an untreated silicon nitride film on the three dimensional structure. The silicon halide precursor comprises substantially no fluorine atoms nor chlorine atoms. The nitrogen precursor comprises substantially no plasma. The untreated silicon nitride film is treated with a plasma to form a treated silicon nitride film. The method is performed at a temperature less than or equal to about 300° C.

Additional embodiments of the disclosure are directed to a deposition method comprising providing a substrate with at least one three dimensional structure formed thereon. The substrate is sequentially exposed at a first processing pressure to a nitrogen precursor for a first period of time and then a silicon halide precursor for a second period of time to form an untreated silicon nitride film on the three dimensional structure. The nitrogen precursor comprises substantially no plasma. The silicon halide precursor comprises substantially no fluorine atoms nor chlorine atoms. The second period being at least 2 times greater than the first period. The untreated silicon nitride film is treated at a second processing pressure with a plasma to form a treated silicon nitride film. The treated silicon nitride film has a conformatlity of greater than about 99%, a lower hydrogen content than the untreated silicon nitride film and is hermetic. The method is performed at a temperature less than or equal to about 300° C. and the second processing pressure is less than the first processing pressure.

Further embodiments of the disclosure are directed to a deposition method comprising providing a substrate with at least one three dimensional structure formed thereon. The three dimensional structure comprises a chalcogen material. The substrate is sequentially exposed at about 20 Torr to a nitrogen precursor consisting essentially of ammonia for a first period of time and tetraiodosilane for a second period of time to form an untreated silicon nitride film on the three dimensional structure. The nitrogen precursor comprising substantially no plasma. The second period being about 2 times greater than the first period. The untreated silicon nitride film is treated at about 0.7 Torr with a plasma of nitrogen gas (N₂) with a power of about 400 W to form a treated silicon nitride film. The treated silicon nitride film has a conformatlity of greater than about 99%, a lower hydrogen content than the untreated silicon nitride film and is hermetic. The method is performed at a temperature of about 250° C.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an exemplary process sequence for the formation of a treated silicon nitride layer according to one or more embodiment of the disclosure;

FIG. 2 illustrates a schematic representation of a substrate with a fin shaped feature thereon in accordance with one or more embodiment of the disclosure;

FIG. 3A illustrates a schematic representation of a substrate with a fin shaped feature thereon comprised of multiple materials in accordance with one or more embodiment of the disclosure; and

FIG. 3B illustrates a schematic representation of a substrate according to FIG. 3A covered by an encapsulation layer in accordance with one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate”, “substrate surface”, or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Embodiments of the disclosure advantageously provide methods of depositing a silicon nitride film at lower temperatures and without the use of chlorine-containing precursors. As used in this regard, “lower temperatures” are evaluated relative to temperatures typically used in thermal CVD and ALD processes. Some embodiments advantageously produce silicon nitride films which are highly conformal (thickness variations of less than 5%), have low etch rates (high etch resistance), lower oxidation (i.e. low atomic oxygen concentrations), higher silicon content and good hermeticity.

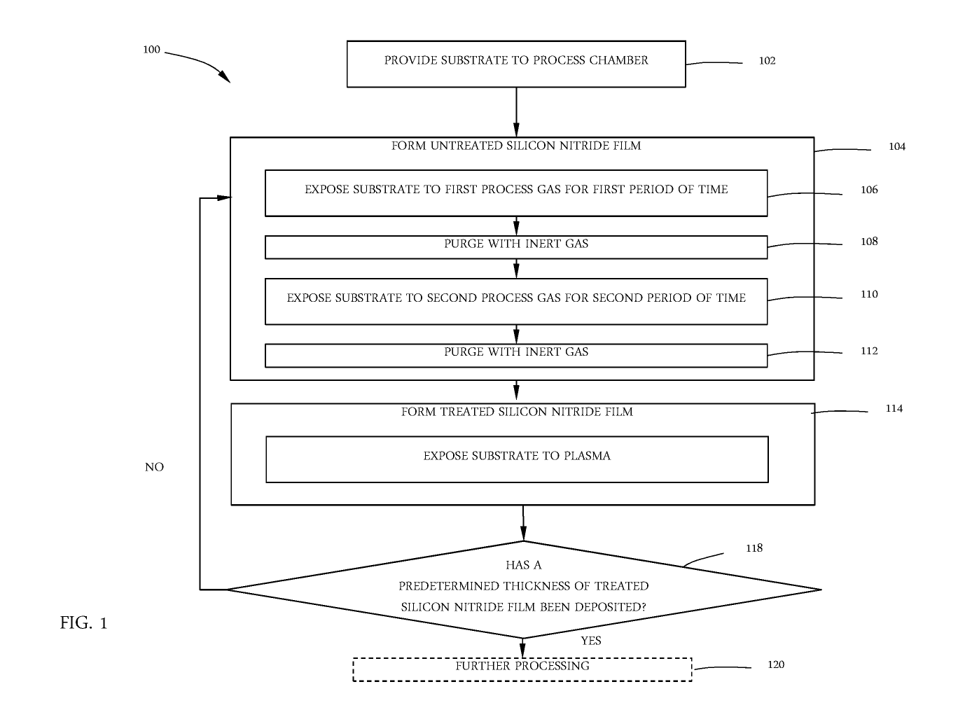

With reference to FIG. 1, one or more embodiment of the disclosure is directed to a method 100 for forming a silicon nitride film on a substrate with at least one three dimensional (3D) structure formed thereon. 3D structures may be formed on the substrate by various patterning and etching processes.

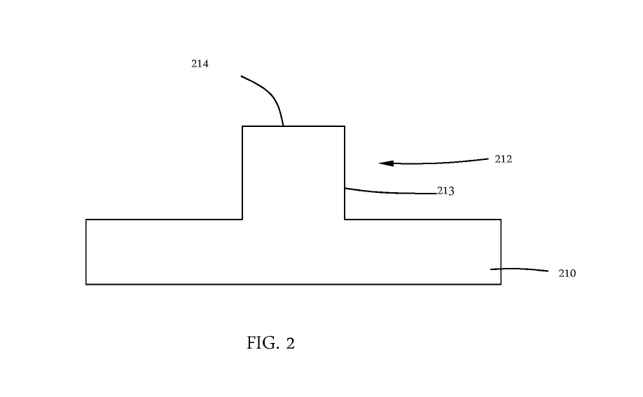

FIG. 2 illustrates an exemplary substrate 210 with a fin 212 formed thereon. The fin 212 comprises at least one sidewall 213 and a top 214. The fin has a height H and a lateral width W. The fin 212 of some embodiments is a rectangular prism-shaped object with elongated sidewalls connected by shorter end walls (not shown). In some embodiments, the fin 212 is a cylindrical object with one round sidewall and a top. In some embodiments, the fin 212 has an aspect ratio of greater than or equal to about 5. As used in this regard, the aspect ratio of a fin is defined as the height H divided by the width W. In some embodiments, the substrate comprises more than one fin and the regions between neighboring fins forms a trench or gap.

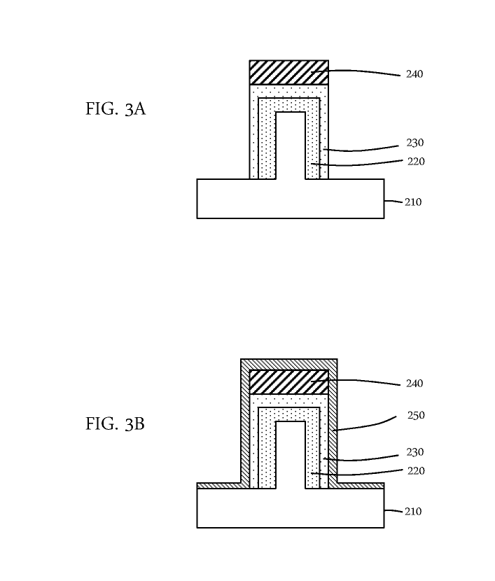

As shown in FIG. 3A, in some embodiments, the fin 212 comprises different materials 220, 230, 240. In some embodiments, the first material 220 may be the same or different from the material of the substrate 210 and the first material 210 forms a fin. In some embodiments, a second material 230 is deposited conformally over the first material 220. In some embodiments, the second material 230 is an oxide liner on the first material 220. In some embodiments, a third material 240 is deposited on the top surface of the second material 230.

In some embodiments, the third material 240 is sensitive to air or moisture. In some embodiments, the third material is sensitive to oxygen. In some embodiments, the second material is sensitive to water. As used in this regard, a material is “sensitive” to an environment or a species within an environment, if the properties of the material are altered after being exposed to the environment or species. The property of the material that is altered may be altered as the result of a physical change (e.g. crystallinity) or a chemical change (e.g. oxidation state contamination).

In some embodiments, the first material comprises silicon, the second material comprises silicon oxide and the third material is a chalcogen material. As used in this regard, a “chalcogen material” is any material comprising a chalcogen. Exemplary chalcogens include sulfur, selenium and tellurium. In some embodiments, the chalcogen material comprises a chalcogen and an element from Group 14 or Group 15 of the Periodic Table. In some embodiments, the third material comprises one or more of AsS, GeS or GeSbTe.

As the third material may be sensitive to air and moisture, some embodiments of this disclosure provide methods of forming a fourth material 250 as a film or encapsulation layer to cover and protect the third material 240, as shown in FIG. 3B. In some embodiments, the encapsulation layer is continuous over the third material and the second material. In some embodiments, the encapsulation layer is hermetic.

Referring again to FIG. 1, the method 100 generally begins at 102 with providing a substrate 210. As used in this manner, “provided” means that the substrate 210 is placed into position or a suitable environment for processing. The substrate 210 has at least one three dimensional structure formed thereon. In some embodiments, the three dimensional structure comprises a fin 212.

At 104, an untreated silicon nitride film is formed on the substrate. The untreated silicon nitride film is formed via a cyclical deposition process, such as atomic layer deposition (ALD), or the like. In some embodiments, the forming of a untreated silicon nitride film via a cyclical deposition process may generally comprise exposing the substrate to two or more process gases sequentially.

In time-domain ALD embodiments, exposure to each of the process gases are separated by a time delay/pause to allow the components of the process gases to adhere and/or react on the substrate surface. Alternatively, or in combination, in some embodiments, a purge may be performed before and/or after the exposure of the substrate to the process gases, wherein an inert gas is used to perform the purge. For example, a first process gas may be provided to the process chamber followed by a purge with an inert gas. Next, a second process gas may be provided to the process chamber followed by a purge with an inert gas. In some embodiments, the inert gas may be continuously provided to the process chamber and the first process gas may be dosed or pulsed into the process chamber followed by a dose or pulse of the second process gas into the process chamber. In such embodiments, a delay or pause may occur between the dose of the first process gas and the second process gas, allowing the continuous flow of inert gas to purge the process chamber between doses of the process gases.

In spatial ALD embodiments, exposure to each of the process gases occurs simultaneously to different parts of the substrate so that one part of the substrate is exposed to the first process gas while a different part of the substrate is exposed to the second process gas (assuming only two process gases are used). The substrate is moved relative to the gas delivery system so that each point on the substrate is sequentially exposed to both the first and second process gases.

A “pulse” or “dose” as used herein is intended to refer to a quantity of a process gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

The process of forming the untreated silicon nitride film at 104 may begin by exposing the substrate to a first reactive gas. In some embodiments, the first reactive gas comprises a nitrogen precursor. The first reactive gas is exposed to the substrate for a first period of time, as shown at 106.

In some embodiments, the nitrogen precursor comprises or consists essentially of one or more of nitrogen gas (N₂), ammonia (NH₃) or hydrazines. The nitrogen precursor comprises substantially no plasma. The nitrogen precursor may be supplied to the substrate surface at a flow rate greater than the silicon halide precursor.

Next, at 108, the process chamber (especially in time-domain ALD) may be purged using an inert gas. (This may not be needed in spatial ALD processes as there are gas curtains separating the reactive gases.) The inert gas may be any inert gas, for example, such as argon, helium, neon or the like. In some embodiments, the inert gas may be the same, or alternatively, may be different from the inert gas provided to the process chamber during the exposure of the substrate to the silicon halide precursor at 106. In embodiments where the inert gas is the same, the purge may be performed by diverting the first process gas from the process chamber, allowing the inert gas to flow through the process chamber, purging the process chamber of any excess first process gas components or reaction byproducts. In some embodiments, the inert gas may be provided at the same flow rate used in conjunction with the first process gas, described above, or in some embodiments, the flow rate may be increased or decreased. For example, in some embodiments, the inert gas may be provided to the process chamber at a flow rate of about 0 to about 10,000 sccm to purge the process chamber. In spatial ALD, purge gas curtains may be maintained between the flows of reactive gases and purging the process chamber may not be necessary. In some embodiments of a spatial ALD process, the process chamber or region of the process chamber may be purged with an inert gas.

The flow of inert gas may facilitate removing any excess first process gas components and/or excess reaction byproducts from the process chamber to prevent unwanted gas phase reactions of the first and second process gases. For example, the flow of inert gas may remove excess silicon halide precursor from the process chamber, preventing a gas phase reaction between the silicon halide precursor and a subsequent reactive gas.

Next, at 110, the substrate is exposed to a second process gas for a second period of time. The second process gas reacts with the silicon halide precursor adsorbed on the substrate surface to create a deposited film. In some embodiments, the second reactive gas is referred to as the nitrogen precursor.

The silicon halide precursor may be any suitable precursor to adsorb a layer of silicon on the substrate for later reaction. Without being bound by theory, it is believed that in some embodiments the presence of chlorine atoms or fluorine atoms in the silicon precursor may etch or otherwise damage the third material. Accordingly, in some embodiments, the silicon halide precursor comprises substantially no fluorine atoms nor fluorine atoms. Stated differently, in some embodiments, the halogen atoms of the silicon halide precursor consist of bromine atoms or iodine atoms. As used in this regard, a silicon halide precursor which comprises substantially no chlorine atoms nor fluorine atoms consists of less than 1%, 0.5%, or 0.1% of halongen atoms on an atomic count basis.

Without being bound by theory, it is believed that the bond energy of silicon-iodine bonds is approximately 40% lower than silicon-chloride bonds, thereby facilitating the deposition of silicon-containing films at lower temperatures than similar techniques which utilize silicon chloride precursors.

In some embodiments, the silicon halide precursor comprises a species with a general formula SiHₐI_{b} where a +b is equal to 4. In some embodiments, the silicon halide precursor comprises a species with a general formula SiH_{c}Br_{d} where c+d is equal to 4. In some embodiments, the silicon halide precursor comprises a species with a general formula SiHₑBr_{f}I_{g} where e+f+g is equal to 4 and neither f nor g is zero. In some embodiments, the silicon halide precursor comprises or consists essentially of one or more of tetraiodosilane (SiI₄), diiodosilane (SiH₂I₂) or tetrabromosiliane (SiBr₄). As used in this specification and the appended claims, the term “consists essentially of” means that the stated reactive gas (not including any carrier gas or diluent gas) is greater than or equal to about 95%, 98%, 99% or 99.5% of the specified species on a molar basis.

Next, at 112, the process chamber may be purged using an inert gas. The inert gas may be any inert gas, for example, such as argon, helium, neon or the like. In some embodiments, the inert gas may be the same, or alternatively, may be different from the inert gas provided to the process chamber during previous process routines. In embodiments where the inert gas is the same, the purge may be performed by diverting the second process gas from the process chamber, allowing the inert gas to flow through the process chamber, purging the process chamber of any excess second process gas components or reaction byproducts. In some embodiments, the inert gas may be provided at the same flow rate used in conjunction with the second process gas, described above, or in some embodiments, the flow rate may be increased or decreased. For example, in some embodiments, the inert gas may be provided to the process chamber at a flow rate of greater than 0 to about 10,000 sccm to purge the process chamber.

In some embodiments, the order in which the silicon halide precursor and the nitrogen precursor are exposed to the substrate may be varied. In some embodiments, the substrate is exposed to the silicon halide precursor before the nitrogen precursor. In some embodiments, the substrate is exposed to the silicon halide precursor after the nitrogen precursor.

The various process parameters for depositing the untreated silicon nitride film may be varied. In some embodiments, the substrate is exposed to the nitrogen precursor for a first period of time and the substrate is exposed to the silicon halide precursor for a second, different, period of time. In some embodiments, the silicon precursor is exposed to the substrate for a period of time about twice as long as the period of time that the substrate is exposed to the nitrogen precursor. In some time-domain ALD embodiments, the first or second period of time may be in the range of about 1 sec to about 120 sec, or in the range of about 2 sec to about 60 sec, or in the range of about 5 sec to about 30 sec.

Next, at 114, a treated silicon nitride film is formed from the untreated silicon nitride film. The untreated silicon nitride film is exposed to a plasma to form a treated silicon nitride film. In some embodiments, the plasma used to treat the untreated silicon nitride film comprises one or more of argon, helium or nitrogen gas (N₂). In some embodiments, the treated silicon nitride film has a lower hydrogen content or lower oxygen content on an atomic count basis than the untreated silicon nitride film. In some embodiments, the treated silicon nitride film has a higher refractive index than the untreated silicon nitride film.

In some embodiments, treating the untreated silicon nitride film utilizes a plasma source. The plasma may be generated remotely or within the processing chamber. Plasma may be inductively coupled plasma (ICP) or conductively coupled plasma (CCP). Treatment can occur at any suitable power depending on, for example, the reactants used, or the process conditions used. In some embodiments, treating the untreated silicon nitride film utilizes a plasma power in the range of about 100 W to about 10 kW. In some embodiments, treating the untreated silicon nitride film utilizes a plasma power greater than or equal to about 100 W, 200 W, 300 W, 400 W, 500 W or 1 kW. In some embodiments, expansion utilizes a plasma power of about 400 W.

In some embodiments, the temperature of the substrate is maintained throughout the method 100. In some embodiments, the substrate is maintained at a temperature in the range of about 25° C. to about 400° C., about 100° C. to about 300° C., or about 150° C. to about 250° C. In some embodiments, the substrate is maintained at a temperature less than or equal to about 400° C., less than or equal to about 350° C., less than or equal to about 300° C., less than or equal to about 275° C., or less than or equal to about 250° C. In some embodiments, the substrate is maintained at a temperature of about 250° C.

The pressure at which the substrate surface is exposed to each of the process gases and/or the plasma can be varied depending on, for example, the reactants selected and other process conditions (e.g. temperature). In some embodiments, exposure to each of the precursors occurs at a pressure in the range of about 0.1 Torr to about 100 Torr. In one or more embodiments, the substrate is exposed at a pressure in the range of about 0.1 Torr to about 100 Torr, or in the range of about 1 Torr to about 50 Torr, or in the range of about 2 Torr to about 30 Torr. In some embodiments, the substrate is exposed to the process gases at a pressure of about 20 Torr.

In some embodiments, the pressure of the process chamber may be varied between forming the untreated silicon nitride film 104 and forming the treated silicon nitride film 114. In some embodiments, forming the untreated silicon nitride film is performed at a higher pressure than treating the untreated silicon nitride film. In some embodiments, the substrate is exposed to the silicon halide precursor and the nitrogen precursor at a pressure of greater than or equal to 5 Torr, greater than or equal to 10 Torr, or greater than or equal to 15 Torr while the treated silicon film is formed at a lower pressure. In some embodiments, the lower pressure is about one half, one third, one fourth, one fifth, one tenth, one twentieth, one thirtieth or one fiftieth the pressure at which the substrate is exposed to the silicon halide precursor and/or the nitrogen precursor. For example, in some embodiments, the substrate is exposed to the silicon halide precursor and the nitrogen precursor at about 20 Torr while the untreated silicon nitride film is treated with a plasma at about 0.7 Torr.

Next, at 118, it is determined whether the treated silicon nitride film has achieved a predetermined thickness. If the predetermined thickness has not been achieved, the method 100 returns to 104 to continue forming the untreated silicon nitride film and treating the untreated silicon nitride film until the predetermined thickness is reached. Once the predetermined thickness has been reached, the method 100 can either end or proceed to 120 for optional further processing. In some embodiments, the treated silicon nitride film may be deposited to form a layer thickness of about 10 to about 100 Å, or in some embodiments, about 30 to about 50 Å.

In some embodiments, the untreated silicon nitride film is substantially conformal to the substrate surface. In some embodiments, the treated silicon nitride film is substantially conformal to the substrate surface. As used in this regard, the term “conformal” means that the thickness of the silicon film is uniform across the substrate surface. As used in this specification and the appended claims, the term “substantially conformal” means that the thickness of the film does not vary by more than about 10%, 5%, 2%, 1%, or 0.5% relative to the average thickness of the film. Stated differently a film which is substantially conformal has a conformality of greater than about 90%, 95%, 98%, 99% or 99.5%.

The treated silicon nitride film is hermetic. As used in this regard, a hermetic film is one which prevents the underlying substrate or film from exposure to air or moisture.

The treated silicon nitride film has high wet etch resistance (i.e., a low etch rate). In some embodiments, the wet etch rate of the treated silicon nitride film in 1000:1 DHF is less than or equal to about 100 Å/min, less than or equal to about 50 Å/min, less than or equal to about 30 Å/min, less than or equal to about 20 Å/min, less than or equal to about 15 Å/min, or less than or equal to about 10 Å/min.

The treated silicon nitride film has a low level of oxidation (i.e. atomic concentration of oxygen). In some embodiments, the atomic concentration of oxygen in the treated silicon nitride film is less than or equal to about 10 atomic percent, less than or equal to about 9 atomic percent, less than or equal to about 8 atomic percent, less than or equal to about 7 atomic percent, or less than or equal to about 6 atomic percent.

One embodiment of the formation of the treated silicon nitride film has been described above. However, it is within the scope of this disclosure that the process of forming the treated silicon nitride film may rely on the exposure of the silicon precursor to a plasma followed by exposure to the nitrogen precursor. This disclosure is intended to provide for the exposure of a substrate to a silicon precursor, a nitrogen precursor and a plasma, in any order, to form a treated silicon nitride film.

Further embodiments of this disclosure relate to the optimization or tuning of the process to achieve superior film properties. In some embodiments, the pressure and/or power of the plasma exposure is modified to achieve superior etch rate, particularly within the features of the substrate. In some embodiments, the method is improved to provide decreased wet etch rates by applying a plasma with decreased pressure. In some embodiments, the pressure is decreased by a factor greater than or equal to about 25, greater than or equal to about 30, or greater than or equal to about 40. In some embodiments, the method is improved to provide decreased wet etch rates on the sidewalls of the features by applying a plasma with an increased power. In some embodiments, the plasma power is increased by a factor greater than or equal to about 50%, greater than or equal to about 75%, or greater than or equal to about 100%.

In some embodiments, the pressure and/or power of the plasma exposure is modified to achieve superior hermeticity of the deposited film and/or thinner films with equivalent hermeticity. In some embodiments, the pressure is decreased by a factor greater than or equal to about 25, greater than or equal to about 30, or greater than or equal to about 40. In some embodiments, the plasma power is increased by a factor greater than or equal to about 50%, greater than or equal to about 75%, or greater than or equal to about 100%. In some embodiments, the thickness of the film is reduced by a factor greater than or equal to about 1.5, greater than or equal to about 2, greater than or equal to about 3 or greater than or equal to about 4.

In some embodiments, the composition of the gas utilized to form the plasma is modified to achieve superior etch rate, film shape and film quality of the silicon nitride film deposited on the top and/or sidewall(s) of substrate. In some embodiments, the plasma comprises Ar and N₂. In these embodiments, the deposited film has better film quality than exposure to N₂ alone, and after exposure to 200:1 DHF for 20 s shows less corner clip than exposure to plasma of Ar alone.

In some embodiments, the exposure time of the silicon precursor and/or nitrogen precursor is modified to achieve a modified film composition and superior etch rate characteristics of the silicon nitride film deposited on the top and/or sidewall(s) of substrate. In some embodiments, the exposure time of the nitrogen precursor is reduced to increase the silicon content of the film. In some embodiments, the etch rate of the film deposited on the sidewall of the substrate is reduced by a factor greater than or equal to about 1.5, greater than or equal to about 2, or greater than or equal to about 3.

In some embodiments, the composition of the silicon precursor is selected to achieve superior throughput, improved film shape, and superior etch rate characteristics of the silicon nitride film deposited on the top and/or sidewall(s) of substrate. In some embodiments, the silicon precursor consists essentially of SiH₂I₂. In some embodiments, the nitrogen to silicon ratio of the deposited film is substantially the same. In some embodiments, the processing time required to achieve a predetermined thickness is shortened by a factor of greater than or equal to about 1.3, greater than or equal to about 1.5 or greater than or equal to 2. In some embodiments, the exposure time of the silicon precursor is reduce by a factor of greater than or equal to about 2, greater than or equal to about 3, greater than or equal to about 4, greater than or equal to about 5 or greater than or equal to about 6. In some embodiments, the exposure time of the nitrogen precursor is reduced by a factor of greater than or equal to about 1.2, greater than or equal to about 1.33 or greater than or equal to about 1.5.

In some embodiments, the deposited film after exposure to 200:1 DHF for 20 s shows less corner clip. In some embodiments, the etch rate of the deposited film is reduced by a factor greater than or equal to about 1.5, greater than or equal to about 2, greater than or equal to about 3 or greater than or equal to about 4 on the top and/or sidewall of the substrate.

### EXAMPLES

### Example 1

Thermal Deposition at 250° C.

Atomic Layer Deposition of silicon nitride was attempted without the use of plasma while the substrate was maintained at 250° C. The substrate was exposed to ammonia at a pressure of 20 Torr for 30 seconds. The chamber was purged with argon at a pressure of 3 Torr for 30 seconds. The substrate was exposed to tetraiodosilane at 20 Torr for 60 seconds. The tetraiodosilane was delivered without Ar dilution. The chamber was purged with argon at a pressure of 3 Torr for 30 seconds. This cycle was repeated 200 times.

The deposited film demonstrated a growth per cycle (GPC) of 0.43 Å/cycle. The refractive index was 1.55. An FTIR analysis showed a strong Si—O band. Elemental analysis provided 43.6% silicon, 42.3% nitrogen and 13.9% oxygen, relating to a N:Si ratio of 0.97.

### Example 2

Thermal Deposition at 400° C.

Atomic Layer Deposition of silicon nitride was attempted without the use of plasma while the substrate was maintained at 400° C. The substrate comprising a three dimensional structure was exposed to ammonia at a pressure of 20 Torr for 30 seconds. The chamber was purged with argon at a pressure of 3 Torr for 30 seconds. The substrate was exposed to tetraiodosilane at 20 Torr for 60 seconds. The tetraiodosilane was delivered without Ar dilution. The chamber was purged with argon at a pressure of 3 Torr for 30 seconds. This cycle was repeated 200 times.

The deposited film demonstrated a growth per cycle (GPC) of 0.39 Å/cycle. The refractive index was 1.70. Elemental analysis provided 43.6% silicon, 45.5% nitrogen and 10.7% oxygen, relating to a N:Si ratio of 1.04. The film thickness on the top surface of the three dimensional structure was 75.2 Å, while the film thickness on the sidewall of the three dimensional structure was 77.7 Å.

The deposited film was exposed to a solution of 1000:1 DHF for 20 seconds. As a result, the deposited film was etched completely from the sidewall of the three dimensional structure. This behavior corresponded to a wet etch rate (WER) of greater than 230 Å/min.

The Applicants noted that the higher deposition temperature provided a film with superior properties. A plasma was determined to be necessary to achieve a high quality film at lower temperatures.

### Example 3

ALD cycle of Ammonia+Tetraiodosilane+N₂ Plasma at 250° C.

Atomic Layer Deposition of silicon nitride with a plasma post-treatment was attempted while the substrate was maintained at 250° C. The substrate comprising a three dimensional structure was exposed to ammonia at a pressure of 20 Torr for 30 seconds. The chamber was purged with argon at a pressure of 3 Torr for 30 seconds. The substrate was exposed to tetraiodosilane at 20 Torr for 60 seconds. The chamber was purged with argon at a pressure of 3 Torr for 35 seconds. The substrate was exposed to a plasma of nitrogen gas (N₂) with a power of 200 W for 5 seconds at 3 Torr. This cycle was repeated 200 times.

The deposited film demonstrated a growth per cycle (GPC) of 0.37 Å/cycle. The refractive index was 1.84. Elemental analysis provided 42.1% silicon, 50.8% nitrogen and 6.6% oxygen, relating to a N:Si ratio of 1.21. The film thickness on the top surface of the three dimensional structure was 71.5 Å, while the film thickness on the sidewall of the three dimensional structure was 78.2 Å.

The deposited film was exposed to a solution of 1000:1 DHF for 20 seconds. As a result, the deposited film thickness on the top surface of the three dimensional structure was reduced to 67.5 Å, while the film thickness on the sidewall of the three dimensional structure was reduced to 72.3 Å. This behavior corresponded to a wet etch rate (WER) on the top surface of about 12.0 Å/min and on the sidewall surface of about 17.7 Å/min.

### Example 4

Test of Hermeticity

A silicon nitride film of about 80 Å was deposited on a SiGe fin by the process of Example 3. The deposited film was exposed to steam at 400° C. for about 2 hours. No degradation of the SiGe was observed. The deposited film was determined to be hermetic.

### Example 5

Plasma-Enhanced ALD at 250° C.

Plasma-Enhanced Atomic Layer Deposition of silicon nitride was attempted while the substrate was maintained at 250° C. The substrate comprising several three dimensional structures positioned so as to form a narrow trench was exposed to tetraiodosilane at 20 Torr for 60 seconds. The chamber was purged with argon at a pressure of 3 Torr for 35 seconds. The substrate was exposed to a plasma of ammonia with a power of 200 W for 5 seconds at 3 Torr. This cycle was repeated 200 times.

The deposited film was observed to be a rough film. The film demonstrated poor uniformity across the substrate surface and poor conformality with no SiN deposited at the bottom of the trench. Elemental analysis of the deposited film provided 43.2% silicon, 43.2% nitrogen and 11.8% oxygen, relating to a N:Si ratio of 1.00.

### Example 6

ALD Cycle of Tetraiodosilane+Ammonia+N₂ Plasma at 250° C.

Atomic Layer Deposition of silicon nitride with a plasma post-treatment was attempted while the substrate was maintained at 250° C. The substrate comprising a three dimensional structure was exposed to tetraiodosilane at 20 Torr for 60 seconds. The chamber was purged with argon at a pressure of 3 Torr for 30 seconds. The substrate was exposed to ammonia at a pressure of 20 Torr for 30 seconds. The chamber was purged with argon at a pressure of 3 Torr for 35 seconds. The substrate was exposed to a plasma of nitrogen gas (N₂) with a power of 200 W for 5 seconds at 3 Torr. This cycle was repeated 200 times.

The deposited film demonstrated a growth per cycle (GPC) of 0.30 Å/cycle. The refractive index was 1.73. FTIR analysis indicated a weaker band related to Si—N bonds than a similar film prepared in Example 3. The film thickness on the top surface of the three dimensional structure was 36.1 Å, while the film thickness on the sidewall of the three dimensional structure was 47.1 Å.

The deposited film was exposed to a solution of 1000:1 DHF for 20 seconds. As a result, the deposited film thickness on the top surface of the three dimensional structure was reduced to 30.8 Å, while the film thickness on the sidewall of the three dimensional structure was reduced to 37.8 Å. This behavior corresponded to a wet etch rate (WER) on the top surface of about 31.8 Å/min and on the sidewall surface of about 55.8 Å/min.

### Example 7

Two silicon nitride films were prepared similar to Example 3 on a substrate comprising several three dimensional structures positioned so as to form a narrow trench. The first film was prepared using an Ar/N₂ plasma with a power of 200 W at 3 Torr. The second film was prepared using an Ar/N₂ plasma with a power of 400 W at 0.7 Torr. Each film was exposed to a solution of 200:1 DHF.

The first film was observed to be etched from the middle to lower portion of the trench. The second film was observed to have good coverage inside the trench.

### Example 8

Decreasing Pressure and/or Increasing Power to Decrease Etch Rate

Three silicon nitride films were prepared similar to Example 3 on a substrate comprising several three dimensional structures positioned so as to form a narrow trench. The first film was prepared using an Ar/N₂ plasma with a power of 200 W at 3 Torr. The second film was prepared using an Ar/N₂ plasma with a power of 200 W at 0.7 Torr. The third film was prepared using an Ar/N₂ plasma with a power of 400 W at 0.7 Torr. Each film was exposed to a solution of 200:1 DHF for 20 s. The film thickness on the top surface of the three dimensional structure and the film thickness on the sidewall of the three dimensional structure were measured for each film before and after exposure to DHF.

Before exposure, the first film had a top thickness of 5 nm and a sidewall thickness at the top of the feature of 5.1 nm. After exposure the top thickness was reduced to 3.86 nm and the sidewall thickness was reduced to 3.07 nm, corresponding to a top etch rate of 34.2 Å/min and a sidewall etch rate of 60.9 Å/min.

Before exposure, the second film had a top thickness of 3.57 nm and a sidewall thickness at the top of the feature of 3.06 nm. After exposure the film was eliminated from the top surface and the sidewall thickness was reduced to 2.55 nm, corresponding to a top etch rate of >107.1 Å/min and a sidewall etch rate of 15.3 Å/min.

Before exposure, the third film had a top thickness of 3.53 nm and a sidewall thickness at the top of the feature of 3.03 nm. After exposure the film was eliminated from the top surface and the sidewall thickness was reduced to 2.55 nm, corresponding to a top etch rate of >105.9 Å/min and a sidewall etch rate of 14.4 Å/min. Further, a measurement of the thickness deeper within the trench was also taken for the third film. Before exposure, the film had a thickness of 3.03 nm. After exposure the film thickness was reduced to 1.01 nm, corresponding to an etch rate of 60.6 Å/min deep within the trench.

These results indicated that films treated with a plasma of lower pressure have lower etch rates on the sidewall at the top of the feature than those treated at a higher pressure. Without being bound by theory, it is believed that the lower pressure allows for the plasma treatment to penetrate deeper into the features and provide a densified film with a lower etch rate. Further, these results indicated that films treated with a plasma of a higher power have lower etch rates on the sidewall at the top of the feature than those treated with a lower power plasma. Without being bound by theory, it is believed that the higher power allows for the plasma treatment to better treat the films in the features and thereby provide a densified film with a lower etch rate.

### Example 9

Decreasing Pressure and/or Increasing Power while Maintaining or Improving Hermeticity

Three silicon nitride films were deposited on a SiGe fin. A first film of about 80 Å was deposited by the process of Example 3 (3 Torr, 200 W plasma). A second film of about 20 Å was deposited by the process of Example 3. A third film of about 20 Å was deposited by the process of Example 3, except the plasma exposure was performed at a pressure of 0.7 Torr and a power of 400 W. The deposited films were exposed to steam at 400° C. for about 2 hours.

As in Example 4, no degradation of the SiGe was observed for the first film. The first film was determined to be hermetic. The second film showed slight oxidation of the SiGe material beneath the deposited film. The second film was determined not to be hermetic. The third film showed no degradation of the SiGe material beneath the deposited film. The third film was determined to be hermetic.

These results indicated that films treated with a plasma of lower pressure and higher power displayed increased hermeticity, even at smaller thicknesses, relative to films treated with higher pressure and lower power. Without being bound by theory, it is believed that the lower pressure and higher power provides a plasma treatment which better treats the film and provides increased resistance to oxidation and increased hermeticity.

### Example 10

Tuning Plasma Composition

Three silicon nitride films were prepared similar to Example 3. The first film was prepared using a plasma of Ar at 0.7 Torr with a power of 400 W. The second film was prepared using a plasma of N₂ ar 0.7 Torr with a power of 400 W. The third film was prepared using a plasma of Ar and N₂ at 1.5 Torr with a power of 400 W. Each film was exposed to 200:1 DHF for 20 s.

The first film displayed a high level of corner clip before etching. As used in this regard, “corner clip” is where a film is deposited on the sidewall surface and the top surface but is substantially thinner at the junction of the sidewall and top surfaces. After etching the first film showed more film remaining in the trench.

The second film did not display any corner clip before or after etching. However, the second film was of lower quality. The third film showed minimal to no corner clip, a better film quality and decreased etch rate within the trench, resulting from deeper sidewall treatment.

### Example 11

Tuning Silicon Content of Deposited Films

Two silicon nitride films were prepared similar to Example 3. The first film was exposed to a 300 W Ar/N₂ plasma at a pressure of 0.7 Torr. The second film was formed using a 15 s ammonia pulse in each cycle and the same Ar/N₂ plasma. Each film was deposited using 150 cycles. Each film was exposed to 200:1 DHF for 20 s.

The first film had a sidewall etch rate of 46.5 Å/min with a N/Si ratio of about 1.43. The second film had a sidewall etch rate of 15.0 Å/min with a N/Si ratio of about 0.90.

These results indicate that films formed with a shorter ammonia exposure contained a relatively high level of silicon relative to nitrogen. Additionally, these silicon-rich films had lower sidewall etch rates than less silicon-rich films. Without being bound by theory, it is believed that the shorter ammonia exposure provides for a decreased nitrogen content and increased silicon content. Further, films with an increased silicon content and/or decreased nitrogen content displayed better etch resistance (lower etch rates).

### Example 12

Tuning Silicon Precursor Composition

Two silicon nitride films were prepared similar to Example 3. The first film was prepared with a 400 W Ar/N₂ plasma at a pressure of 0.7 Torr, the silicon precursor consisted essentially of SiI₄. The ampoule was maintained at 110° C. The second film was prepared with an ammonia pulse of 20 s, a silicon precursor pulse of 10 s and a 400 W Ar/N₂ plasma at a pressure of 0.7 Torr, the silicon precursor consisted essentially of SiH₂I₂. The ampoule was maintained at 45° C.

The first film was deposited using 150 cycles. The N/Si ratio of the first film was about 1.43. The first film displayed some corner clip. The second film was deposited using 100 cycles. The N/Si ratio of the second film was about 1.48. The second film displayed less corner clip. Both films were exposed to 200:1 DHF for 20 s.

After 7.5 hours of processing on a blanket substrate, a film produced by the same process as the first film had a thickness of 86.6 Å. After 3.5 hours of processing on a blanket substrate, a film produced by the same process as the second film had a thickness of 114 Å.

Before exposure, the first film had a top thickness of 4.41 nm and a sidewall thickness of 4.41 nm. After exposure the film was eliminated from the top surface and the sidewall thickness was reduced to 2.86 nm, corresponding to a top etch rate of >132.3 Å/min and a sidewall etch rate of 46.5 Å/min.

Before exposure, the second film had a top thickness of 5.88 nm and a sidewall thickness of 6.12 nm. After exposure the top thickness was reduced to 4.80 nm and the sidewall thickness was reduced to 5.43 nm, corresponding to a top etch rate of 32.4 Å/min and a sidewall etch rate of 20.7 Å/min.

These results indicated that films formed using SiH₂I₂ were produced with a higher throughput, had lower etch rates on the top surface and sidewall of the feature, and had less corner clip than those formed using SiI₄. Without being bound by theory, it is believed that SiH₂I₂ has better reactivity due to decreased steric hindrances, allowing for a faster deposition. Similarly, it may be that the increased volatility of SiH₂I₂ relative to SiI₄ provided for a faster reaction with the substrate surface. Further, the lower halogen concentration of SiH₂I₂ may have allowed for the formation of a denser film since less volatile halogen gas is produced during processing.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A deposition method comprising:
providing a substrate with at least one three dimensional structure formed thereon;
sequentially exposing the substrate to a nitrogen precursor and a silicon halide precursor to form an untreated silicon nitride film on the three dimensional structure, the nitrogen precursor comprising substantially no plasma. the silicon halide precursor comprising substantially no fluorine atoms nor chlorine atoms; and
treating the untreated silicon nitride film with a plasma to form a treated silicon nitride film,
wherein the method is performed at a temperature less than or equal to about 300° C.

2. The method of claim 1, wherein the three dimensional structure comprises a fin, the fin comprising at least a first material, a second material and a third material, the second material comprising an oxide liner on the first material or the substrate, the third material deposited on a exposed surface of the second material.

3. The method of claim 2, wherein the third material is sensitive to air or moisture.

4. The method of claim 3, wherein the third material comprises a chalcogen material.

5. The method of claim 2, wherein the treated silicon nitride film forms an encapsulation layer over the third material.

6. The method of claim 1, wherein the three dimensional structure has an aspect ratio of greater than or equal to about 5.

7. The method of claim 1, wherein the silicon halide precursor comprises a species with a general formula SiHₐI_{b} where a+b is equal to 4.

8. The method of claim 7, wherein the silicon halide precursor consists essentially of SiI₄.

9. The method of claim 1, wherein the nitrogen precursor comprises one or more of nitrogen gas (N₂), ammonia (NH₃), or hydrazines.

10. The method of claim 9, wherein the nitrogen precursor consists essentially of ammonia.

11. The method of claim 1, wherein the substrate is exposed to the silicon halide precursor after the nitrogen precursor.

12. The method of claim 1, wherein the substrate is exposed to the nitrogen precursor for a first period of time and the silicon halide precursor for a second period of time, the second period being about 2 times greater than the first period.

13. The method of claim 1, wherein the plasma comprises one or more of argon, helium or nitrogen gas (N₂).

14. The method of claim 1, wherein the treated silicon nitride film has a lower hydrogen content than the untreated silicon nitride film.

15. The method of claim 1, wherein forming the untreated silicon nitride film is performed at a higher pressure than treating the untreated silicon nitride film.

16. The method of claim 1, wherein the treated silicon nitride film has a conformality of greater than or equal to about 99%.

17. The method of claim 1, wherein the treated silicon nitride film is hermetic.

18. The method of claim 1, further comprising repeating exposure of the substrate to the nitrogen precursor and the silicon halide precursor and treatment of the untreated silicon nitride film until a treated silicon nitride film of a predetermined thickness has been formed.

19. A deposition method comprising:
providing a substrate with at least one three dimensional structure formed thereon;
sequentially exposing the substrate at a first processing pressure to a nitrogen precursor for a first period of time and then a silicon halide precursor for a second period of time to form an untreated silicon nitride film on the three dimensional structure, the nitrogen precursor comprising substantially no plasma, the silicon halide precursor comprising substantially no fluorine atoms nor chlorine atoms, the second period being at least 2 times greater than the first period; and
treating the untreated silicon nitride film at a second processing pressure with a plasma to form a treated silicon nitride film, the treated silicon nitride film having a conformatlity of greater than about 99%, a lower hydrogen content than the untreated silicon nitride film and being hermetic,
wherein the method is performed at a temperature less than or equal to about 300° C. and the second processing pressure is less than the first processing pressure.

20. A deposition method comprising:
providing a substrate with at least one three dimensional structure formed thereon, the three dimensional structure comprising a chalcogen material;
sequentially exposing the substrate at about 20 Torr to a nitrogen precursor consisting essentially of ammonia for a first period of time and tetraiodosilane for a second period of time to form an untreated silicon nitride film on the three dimensional structure, the nitrogen precursor comprising substantially no plasma, the second period being about 2 times greater than the first period; and
treating the untreated silicon nitride film at about 0.7 Torr with a plasma of nitrogen gas (N₂) with a power of about 400 W to form a treated silicon nitride film, the treated silicon nitride film having a conformatlity of greater than about 99%, a lower hydrogen content than the untreated silicon nitride film and being hermetic,
wherein the method is performed at a temperature of about 250° C.
